(19) United States
(12) Patent Application Publication
(10) Pub. No.: US 2025/0130149 A1
(43) Pub. Date: Apr. 24, 2025

(54) DRIVING DEVICE FOR DETECTING MECHANICAL CHARACTERISTICS AND ELECTRICAL CHARACTERISTICS OF CELLS

(71) Applicant: Zhejiang Normal University, Jinhua (CN)

(72) Inventors: Jianping LI, Jinhua (CN); Jianming WEN, Jinhua (CN); Yili HU, Jinhua (CN); Jijie MA, Jinhua (CN); Junwu KAN, Jinhua (CN); Zhonghua ZHANG, Jinhua (CN); Song CHEN, Jinhua (CN); Yingting WANG, Jinhua (CN); Kang CHEN, Jinhua (CN); Shuqi JIANG, Jinhua (CN); Guangming CHENG, Jinhua (CN); Nen WAN, Jinhua (CN)

(73) Assignee: Zhejiang Normal University, Jinhua (CN)

(21) Appl. No.: 18/818,121

(22) Filed: Aug. 28, 2024

(30) Foreign Application Priority Data
Oct. 24, 2023 (CN) 202311377667.9

(51) Int. Cl. G01N 3/08; G01N 27/22; H02N 2/04; H10N 30/88

(52) U.S. Cl. CPC G01N 3/08; H02N 2/043; H10N 30/886; G01N 27/226; G01N 2203/0051; G01N 2203/0206

(57) ABSTRACT

Provided is a driving device for detecting mechanical characteristics and electrical characteristics of cells. A structure of the driving device includes a piezoelectric stack, a bridge-type flexible hinge mechanism, a parallel hinge mechanism, a lead screw guide rail, a stepping motor, a linear displacement sensor, a force sensor, a ceramic needle, a first electrode, a second electrode, a cell container, an XY axis displacement platform, a positioning hole, a first metal base, a second metal base, a first metal connecting plate, a second metal connecting plate, a first pre-tightening wedge, a second pre-tightening wedge, screws, and a pre-tightening screw. During the operation of the driving device, the piezoelectric stack is driven under an excitation effect of a driving electric field signal, such that the bridge-type flexible hinge mechanism stretches, and the ceramic needle is driven by the parallel flexible hinge mechanism to move downwards.

### CROSS-REFERENCE TO RELATED APPLICATION

This patent application claims the benefit and priority of Chinese Patent Application No. 202311377667.9 filed with the China National Intellectual Property Administration on Oct. 24, 2023, the disclosure of which is incorporated by reference herein in its entirety as part of the present application.

### TECHNICAL FIELD

The present disclosure relates to the research fields of precision ultra-precision machining and micro-mechanical electronic system engineering, in particular to a driving device for detecting mechanical characteristics and electrical characteristics of cells.

### BACKGROUND

With the development of science and technology, micro/nano-scale precision driving technology is the key technology in the research fields, such as precision/ultra-precision machining and measurement, micro-mechanical electronic system, aerospace, biomedicine and the like. Each type of driver has its own advantages. Piezoelectric drivers have the characteristics, such as simple structure, convenient control, high resolution and accurate positioning, and have shown good application effects and bright prospects especially in micro-electromechanical systems, micro-nano indentation, and biological cell operation projects.

Most of the existing devices for detecting characteristics of cell only have one detection function, that is, only the mechanical characteristics of cells or only the electrical characteristics of cells are detected, and the detection of the mechanical characteristics and the detection of the electrical characteristics are not combined. At present, atomic force microscopy, micropipette aspiration technology, optical tweezers technology and microfluidic technology are usually used to detect the mechanical characteristics of cells. Patch clamp, electrochemical impedance analysis and rotating electric field technology are usually used to detect the electrical characteristics of cells. These technologies have some shortcomings, such as complex structure, difficult operation, and high research cost. Therefore, it is required to design a driving device which has the functions of detecting mechanical characteristics and electrical characteristics at the same time, so as to solve the barrier in the prior art and reduce the research cost.

### SUMMARY

An objective of the present disclosure is to provide a driving device for detecting mechanical characteristics and electrical characteristics of cells, so as to solve the problems in the prior art. The present disclosure is simple and compact in structure, and has the functions of detecting mechanical characteristics and electrical characteristics at the same time.

According to the present disclosure, two driving units is used for linear motion, an output of large displacement is achieved by a lead screw guide rail, and an output of small displacement can achieve downward linear motion by the deformation of a piezoelectric stack and two flexible hinge mechanisms. The mechanical characteristics of cells are detected by the combination of a force sensor and a ceramic needle. In order to observe the tiny displacement of the actual descending of the driving device, a linear displacement sensor is used to obtain micron-scale displacement; and meanwhile, the electrical characteristics of cells are detected by an electrical impedance analyzer through the connection of electrodes.

The objective of the present disclosure is achieved through the following technical solution:

A driving device for detecting mechanical characteristics and electrical characteristics of cells mainly includes a piezoelectric stack, a bridge-type flexible hinge mechanism, a parallel hinge mechanism, a lead screw guide rail, a stepping motor, a linear displacement sensor, a force sensor, a ceramic needle, a first electrode, a second electrode, a cell container, an XY axis displacement platform, a positioning hole, a first metal base, a second metal base, a first metal connecting plate, a second metal connecting plate, a first pre-tightening wedge, a second pre-tightening wedge, a pre-tightening screw, and screws. The driving device achieves micro-scale precise linear driving. The lead screw guide rail is fixed to the first metal base. A driver main body includes a bridge-type flexible hinge mechanism, and a parallel flexible hinge mechanism, and is fixed to the first metal connecting plate by screws. The first metal connecting plate is fixed to the lead screw guide rail by the screws. The cell container is arranged above the XY axis displacement platform, and adjusted to an appropriate position through the XY axis displacement platform. The first pre-tightening wedge and the second pre-tightening wedge are pre-tightened by the pre-tightening screw, and fixed to the first metal base by screws. The linear displacement sensor is mounted in the first pre-tightening wedge, and the first metal base and the second metal base are configured for supporting, mounting and fixing other parts. The force sensor is connected to the ceramic needle, and the ceramic needle is made of zirconia, alumina and silicon carbide materials. The first electrode is attached to the ceramic needle, and the second electrode is attached to the bottom of the cell container. The first electrode and the second electrode are connected to an electrical impedance analyzer. In a downward linear motion of the driving device, the ceramic needle is pressed down into the cell container to detect the mechanical characteristics and electrical characteristics of cells.

The detected mechanical characteristics include an elastic modulus, Poisson's ratio, a shear modulus, and the degree of deformation. The detected electrical properties include impedance, a hysteresis frequency, conductivity, a dielectric constant, and cell membrane specific capacitance.

A displacement of the driving device is divided into two steps: firstly, the piezoelectric stack, the bridge-type flexible hinge mechanism, the parallel hinge mechanism, the first metal connecting plate, the second metal connecting plate, the force sensor and the ceramic needle are driven to displace downwards by the lead screw guide rail and a metal adapter plate connected to the lead screw guide rail; and secondly, the piezoelectric stack is arranged in the bridge-type flexible hinge mechanism, the piezoelectric stack is driven to make the bridge-type flexible hinge mechanism to stretch and then to drive the parallel flexible hinge mechanism to stretch and linearly move downwards.

A displacement detection mechanism of the driving device is achieved through the linear displacement sensor. Displacement data of the driving device can be obtained by detecting the tiny displacement of the driving device. The driving device adopts the force sensor for detecting the mechanical characteristics of cells. The XY axis displacement platform can achieve the positioning of the cell container in the X axis and the Y axis.

The bridge-type flexible hinge mechanism and the parallel hinge mechanism may be made of high-strength aluminum alloy. Through a connection of the two flexible hinges, the driving device is good in stiffness output characteristics, large in the output load, and more compact in the size of the structure.

The first pre-tightening wedge and the second pre-tightening wedge are used to fix the linear displacement sensor to the second metal connecting plate to achieve a wedge connection, an initial pre-tightening force of the linear displacement sensor is adjusted by the first pre-tightening wedge, the second pre-tightening wedge and the pre-tightening screw, and the first pre-tightening wedge and the second pre-tightening wedge can be made of a plastic material.

The piezoelectric stack is arranged in the bridge-type flexible hinge mechanism, and the piezoelectric stack is driven to stretch the bridge-type flexible hinge mechanism. Meanwhile, the lower parallel hinge mechanism also stretches to play a role of guiding, such that the driver main body can make linear precise motion without deformation.

A driving device for detecting mechanical characteristics and electrical characteristics of cells is provided. A piezoelectric module is mounted on one side of a first metal base, a guide rail is slidingly mounted in the piezoelectric module, and a fine-tuning element is mounted on one side of the piezoelectric module, and capable of adjusting a pressing force of the piezoelectric module on the guide rail. The piezoelectric module can drive the guide rail to move in a vertical direction when deforms. A lower end of the guide rail is connected to an upper end of a ceramic needle and can drive the ceramic needle to ascend and descend. A first electrode is arranged at a lower end of the ceramic needle, the cell container is located below the ceramic needle, and a second electrode and cells are arranged in the cell container. The first electrode corresponds to the second electrode in position. A force sensor is located at a lower end of the cell container, and a linear displacement sensor is configured to detect the displacement of the guide rail.

The present disclosure has the main advantages that two driving units are used to achieve rough measurement and accurate measurement of displacement. A first displacement of the driver main body is obtained through the lead screw guide rail. Then, by driving the piezoelectric stack, a second displacement of the driver main body is obtained by the linear displacement sensor. The sum of the two displacements is the total displacement of the whole driving device. The mechanical characteristics of cells are detected by the force sensor, and the electrical characteristics of cells are detected by the electrical impedance analyzer. The present disclosure has the advantages of simple structure, novel mode, high driving reliability, low investment and high benefit, which is suitable for important scientific engineering fields such as precision/ultra-precision machining, micro-mechanical electronic systems, modern medicine and biological genetic engineering, biotechnology and the like.

### BRIEF DESCRIPTION OF THE DRAWINGS

FIG. 1 is a diagram of an overall structure of the present disclosure;

FIG. 2 is a left view of the present disclosure;

FIG. 3 is a local cross-sectional view of electrical characteristic measurement of the present disclosure;

FIG. 4 is a diagram of a driver main body of the present disclosure;

FIG. 5 is a diagram of a motion process of a driver main body of the present disclosure;

FIG. 6 is a force-displacement diagram;

FIG. 7 is a diagram of an overall structure of Embodiment 2;

FIG. 8 is a structural diagram of a first electrode of Embodiment 2;

FIG. 9 is a structural diagram of a second electrode of Embodiment 2.

### DETAILED DESCRIPTION OF THE EMBODIMENTS

The detailed content and specific embodiments of the present disclosure are further described below in conjunction with accompanying drawings.

### Embodiment 1

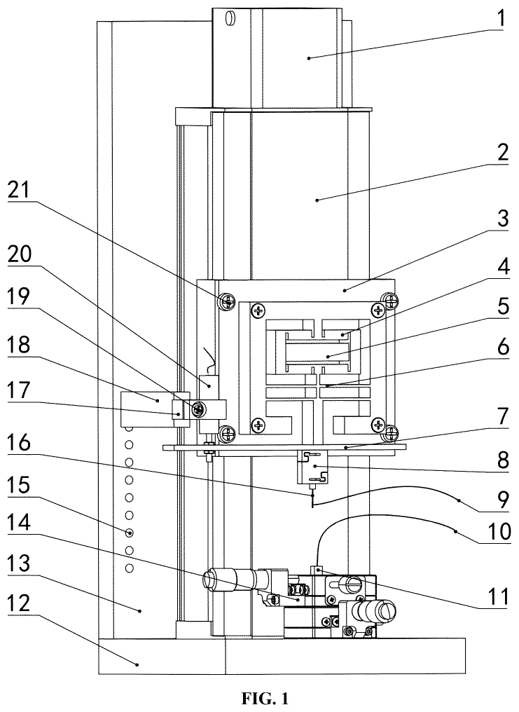

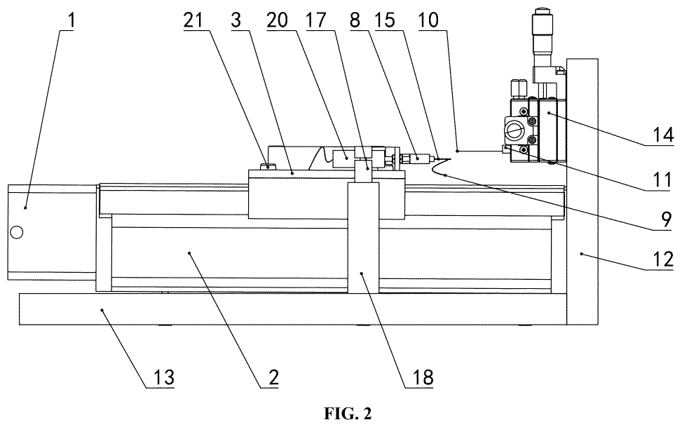

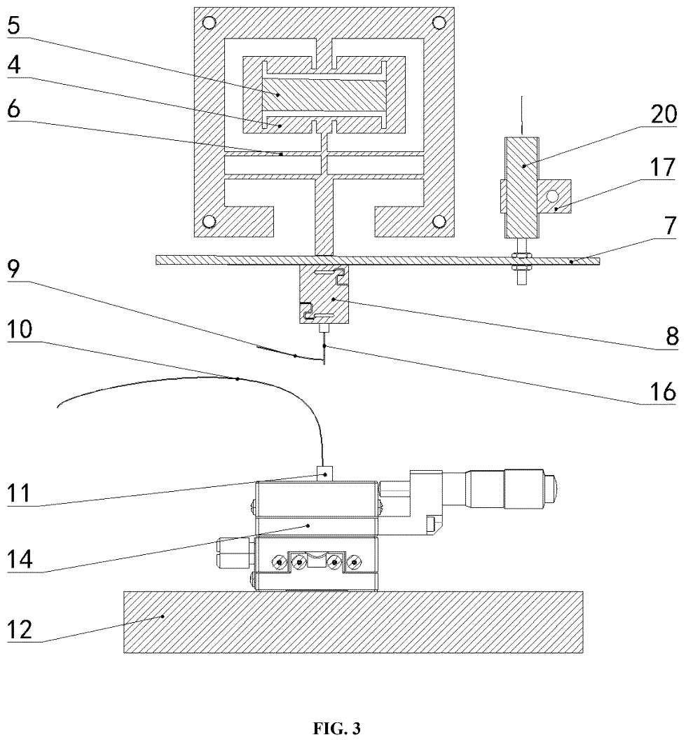

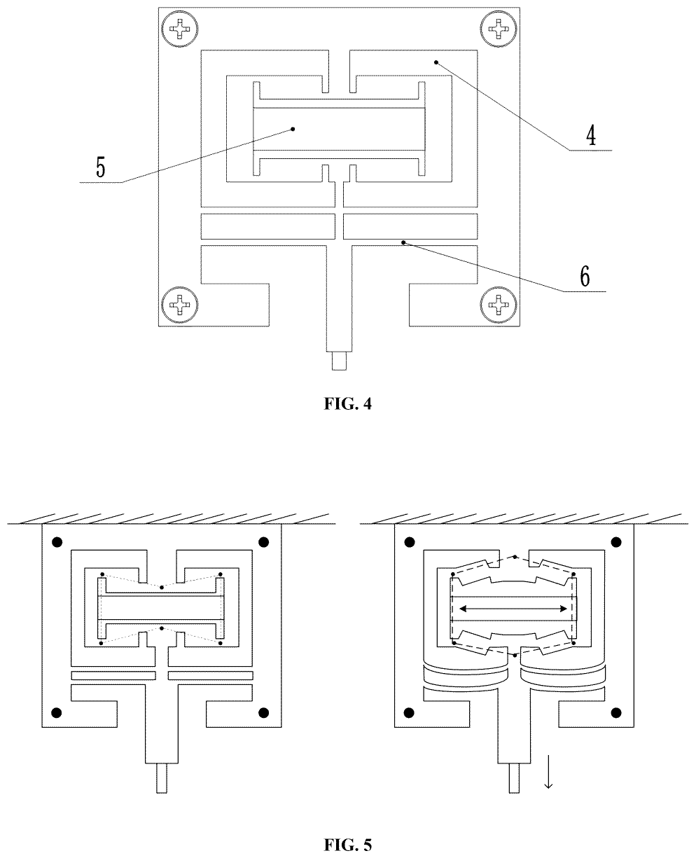

Referring to FIG. 1 to FIG. 5, a driving device for detecting mechanical characteristics and electrical characteristics of cells mainly includes a piezoelectric stack 5, a bridge-type flexible hinge mechanism 4, a parallel hinge mechanism 6, a lead screw guide rail 2, a stepping motor 1, a linear displacement sensor 20, a force sensor 8, a ceramic needle 16, a first electrode 9, a second electrode 10, a cell container 11, an XY axis displacement platform 14, a positioning hole 15, a first metal base 13, a second metal base 12, a first metal connecting plate 3, a second metal connecting plate 7, a first pre-tightening wedge 17, a second pre-tightening wedge 18, a pre-tightening screw 19, and screws 21. The driving device achieves micro-scale precise linear driving. The lead screw guide rail 2 is mounted on the first metal base 13. A driver main body includes the piezoelectric stack 5, the bridge-type flexible hinge mechanism 4 and the parallel flexible hinge mechanism 6 which are mounted on the first metal connecting plate 3 by screws. The first metal connecting plate 3 is fixed to the lead screw guide rail 2 by the screws 21. The linear displacement sensor 20 is fixed and connected to the second metal connecting plate 7 and the first metal base 13 by screws through the first pre-tightening wedge 17 and the second pre-tightening wedge 18, respectively. A positioning adjustable function of the linear displacement sensor 20 can be achieved by the screws. The force sensor 8 and the ceramic needle 16 are connected to the driver main body via the second metal connecting plate 7.

The driving device achieves the micron-scale linear displacement motion of the driver main body by means of the piezoelectric effect and the flexible hinge mechanism. The bridge-type flexible hinge mechanism 4 and the parallel flexible hinge 6 included in the driver main body are good in stiffness output performance, and stable and efficient in motion. The piezoelectric stack 5 is mounted in the bridge-type flexible hinge mechanism 4. When the piezoelectric stack 5 is driven, the bridge-type flexible hinge mechanism 4 deforms, i.e., stretches downwards, and the parallel flexible hinge mechanism 6 connected to the bridge-type flexible hinge mechanism 4 stretches at the same time, the parallel flexible hinge mechanism 6 plays a role in guidance in the driver main body, such that the driver is free of deviating a trajectory when making a linear motion.

An initial pre-tightening force of the linear displacement sensor 20 is provided by the cooperation of the first pre-tightening wedge 17 and the pre-tightening screw 19. The second pre-tightening wedge 18 is mounted and fixed to the first metal base 13 by screws, the linear displacement sensor 20 is fixed to the second metal connecting plate 7 at the same time, and a position of the second pre-tightening wedge 18 is adjusted through a positioning hole 15 in the first metal base 13.

The force sensor 8 is in cooperation with the ceramic needle 16. During the linear motion of the driver main body, the ceramic needle 16 is in contact with the cells, a force signal can be returned and transmitted to an upper computer for displaying, thus achieving the purpose of monitoring in real time.

The first electrode 9 is attached to the ceramic needle 16, the second electrode 10 is attached to the cell container. When the ceramic needle 16 moves downwards, the first electrode 9 and the second electrode 10 are connected to an electrical impedance analyzer to measure the electrical characteristics of cells.

The detected mechanical characteristics include an elastic modulus, Poisson's ratio, a shear modulus, and the degree of deformation. The detected electrical characteristics include impedance, a hysteresis frequency, conductivity, a dielectric constant, and cell membrane specific capacitance.

As shown in FIGS. 1 to 6, the specific working process of the present disclosure is as follows:

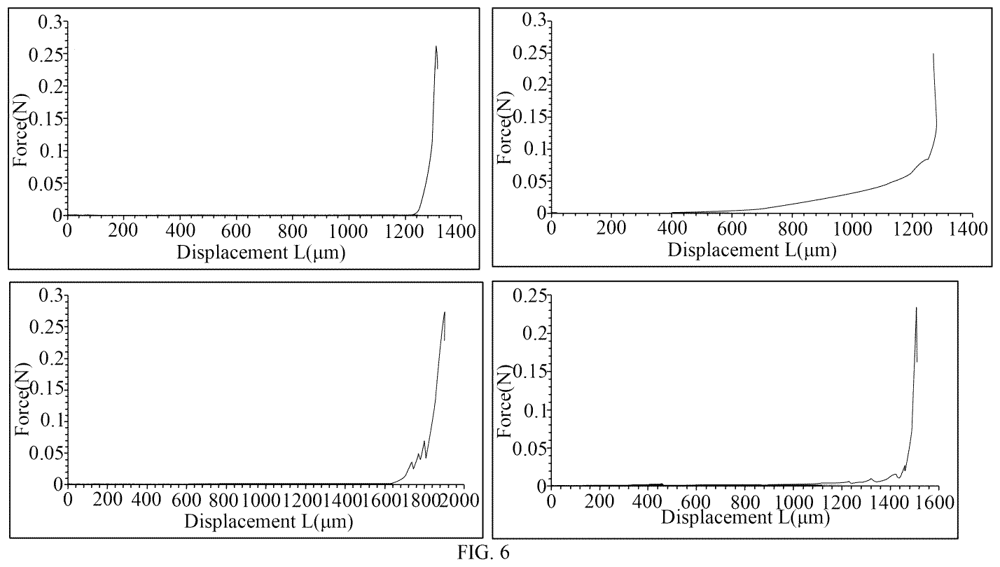

A linear displacement is achieved by two driving units, a first driving unit is achieved by the lead screw guide rail 2, the stepping motor 1 is controlled by the controller, and the lead screw guide rail 2 performs an appropriate displacement, thus achieving a large linear displacement. A second driving unit is achieved by the driver main body. The driver main body includes the piezoelectric stack 5, the bridge-type flexible hinge mechanism 4, and the parallel flexible hinge mechanism 6. The piezoelectric stack 5 is placed in the bridge-type flexible hinge mechanism 4, the piezoelectric stack 5 is driven, and the bridge-type flexible hinge mechanism 4 stretches and displaces downwards, and the lower parallel hinge mechanism 6 also stretches to play a role in guidance, thus remaining a motion trajectory of the driver main body unchanged. When the driver main body makes linear movement downwards, the linear displacement sensor 20 on a left side of the driving device detects a tiny displacement of the driver main body. The linear displacement sensor 20 is fixed to a position between a positioning hole 15 of the first metal base 13 and the second metal connecting plate 7 by screws and by using the first pre-tightening wedge 17 and the second pre-tightening wedge 19, thus achieving the function of detecting the tiny displacement. Meanwhile, the displacement data can be detected in real time by the upper computer. The force sensor 8 connected below the driver main body is in cooperation with the ceramic needle 16, the mechanical characteristics of the cells can be detected by the force sensor 8 in the process that the ceramic needle 16 contacts the cell to crush the cell, thus obtaining a force-displacement diagram, as shown in FIG. 6. The first electrode 9 and the second electrode 10 are connected to an electrical impedance analyzer to detect the corresponding electrical characteristics of cells.

The present disclosure relates to a driving device for detecting the mechanical characteristics and electrical characteristics of cells. Two driving units, a linear displacement sensor and a force sensor are used as main detection devices, and the electrical characteristics are detected through an electrical impedance analyzer. The driving device has the characteristics of simple and compact structure, stable and reliable driving, integrated function and real-time data display, and can effectively detect the mechanical characteristics and electrical characteristics of the cells, and reflect the state of the cells.

### Embodiment 2

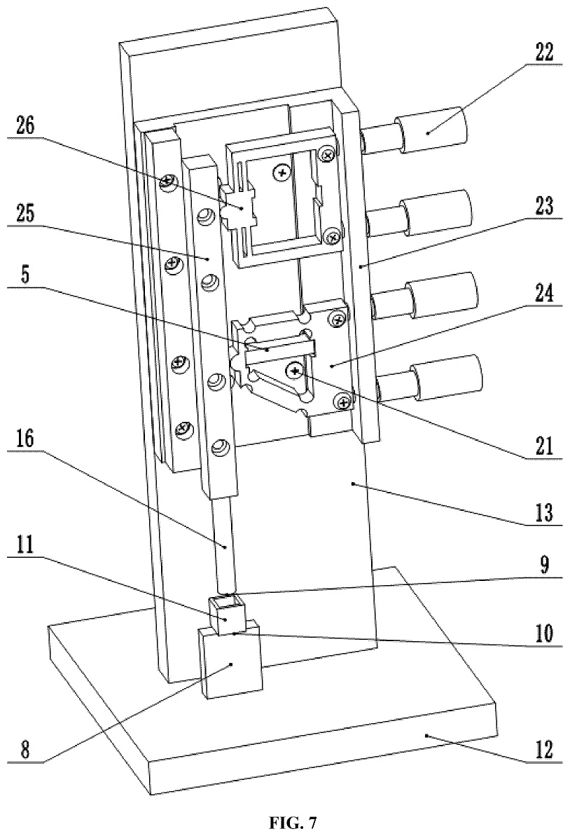

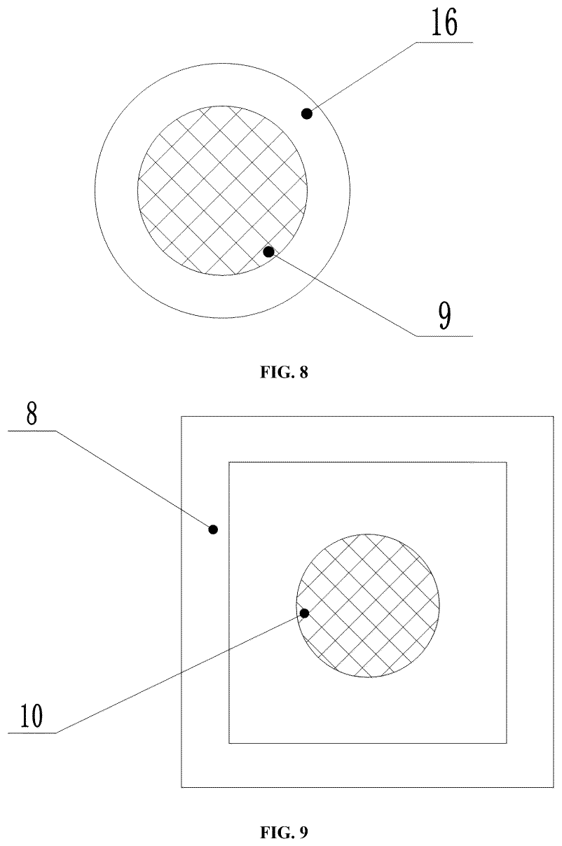

As shown in FIG. 7 to FIG. 9, the piezoelectric module in this embodiment is mounted on one side of the first metal base 13, the guide rail 25 is slidingly mounted in the piezoelectric module, and the fine-tuning element 22 is located on one side of the piezoelectric module and can adjust a pressing force of the piezoelectric module on the guide rail 25. The piezoelectric module drives the guide rail 25 to ascend and descend when deforms. The stick-slip friction inertia piezoelectric drive has the functions of detecting the mechanical characteristics and electrical characteristics of the cells. A lower end of the guide rail 25 is connected to the ceramic needle 16 and can drive the ceramic needle 16 to ascend and descend. A lower end of the ceramic needle 16 is provided with the first electrode 9, and the cell container 11 containing cells is located below the ceramic needle 16 and is provided with the second electrode 10 on the inner bottom surface. The two electrodes correspond to each other in a vertical direction to ensure that an electric field generated after connecting the electrical impedance analyzer is perpendicular to the two electrodes, moreover, an electrical signal is transmitted in the compression process, and the electrical characteristics of the cells are detected. The force sensor 8 is locate at the lower end of the cell container 11, the ceramic needle 16 drives the first electrode 9 to ascend and descend to compress the cells, the acting force is collected by the force sensor 8 in real time and fed back to a computer. The real-time displacement data of the guide rail 25 detected by the linear displacement sensor 20 is fed back to the computer to detect the mechanical characteristics of the cells.

The first metal base 13 and the force sensor 8 are both mounted on the second metal base 12.

The piezoelectric module includes a housing 23, a symmetric flexible hinge 26, an asymmetric flexible hinge 24, and a piezoelectric stack 5. The housing 23 is mounted on the first metal base 13, and the symmetric flexible hinge 26 and the asymmetric flexible hinge 24 are vertically arranged in the housing 23. The piezoelectric stack 5 is mounted in the asymmetric flexible hinge 24 and connected to an external signal generator, so as to stretch under the action of an input signal and drive the asymmetric flexible hinge 24 to deform, and the piezoelectric stack can work as long as an input signal is switched on, thus achieving simultaneous detection of mechanical characteristics and electrical characteristics of the cells. The specific characteristics are the same as those in Embodiment I. The guide rail 25 is located in the housing 23 and at one side of each of the two flexible hinges. The asymmetric flexible hinge 24, when deforms, is in contact with the guide rail 25 to generate a friction and push the guide rail 25 to move downwards, thus compressing the cells by the ceramic needle 16.

The piezoelectric stack 5, after being powered on, slowly stretches to deform the asymmetric flexible hinge 24, thus pushing the guide rail 25 to move forward by a certain distance through friction. After powered off, the piezoelectric stack 5 contracts rapidly, the asymmetric flexible hinge 24 is reset, and the expansion and contraction speed is achieved by controlling an electric field signal.

The housing 23 is mounted on the first metal base 13 by the screws 21, and the two flexible hinges are mounted in the housing 23 by the screws 21.

The fine-tuning element 22 is mounted on one side, away from the guide rail 25, of the housing 23, passes through the housing 23 and acts on the two flexible hinges, so as to adjust pre-tightening forces between the two flexible hinges and the guide rail, respectively, and ensure that the guide rail 25 does not fall due to its own weight under the action of friction. The asymmetric flexible hinge 24 can be deformed and the guide rail 25 can be pushed to descend stably when the piezoelectric stack 5 stretches. The fine-tuning element 22 includes multiple fine-tuning knobs threadedly connected to a side wall of the housing 23, and the fine-tuning knobs are abutted against an outer wall of the symmetric flexible hinge 26 or the asymmetric flexible hinge 24.

A pair of limit grooves is symmetrically formed in two opposite inner walls of the asymmetric flexible hinge 24. The asymmetric flexible hinge is provided with a limit bump at a position close to an outer wall of the guide rail 25 and corresponding to the limit grooves. Both ends of the piezoelectric stack 5 are respectively embedded in the two limit grooves, the stretching of the piezoelectric stack 5 can drive the limiting grooves to deform and the limit bump to move downwards, and the limit bump drives the guide rail 25 to move downwards. The piezoelectric stack 5 is reset, each structure of the asymmetric flexible hinge 24 is also reset, and the guide rail 25 moves upwards.

What is claimed is:

1. A driving device for detecting mechanical characteristics and electrical characteristics of cells, comprising a piezoelectric stack, a bridge-type flexible hinge mechanism, a parallel hinge mechanism, a lead screw guide rail, a stepping motor, a linear displacement sensor, a force sensor, a ceramic needle, a first electrode, a second electrode, a cell container, an XY axis displacement platform, a positioning hole, a first metal base, a second metal base, a first metal connecting plate, a second metal connecting plate, a first pre-tightening wedge, a second pre-tightening wedge, a pre-tightening screw, and screws,
wherein the lead screw guide rail is fixed to the first metal base; a driver main body of the driving device comprises the bridge-type flexible hinge mechanism and the parallel flexible hinge mechanism which are fixed to the first metal connecting plate by screws; the first metal connecting plate is fixed to the lead screw guide rail by the screws; the cell container is arranged above the XY axis displacement platform, and is adjusted to an appropriate position through the XY axis displacement platform; the first pre-tightening wedge and the second pre-tightening wedge are pre-tightened by the pre-tightening screw, and the second pre-tightening wedge is fixed to the first metal base by screws; the linear displacement sensor is mounted in the first pre-tightening wedge, the first metal base and the second metal base are configured for supporting, mounting and fixing other elements, and
wherein the force sensor and the ceramic needle are fixed below the driver main body by the second metal connecting plate, the first electrode is attached to the ceramic needle, and the second electrode is attached to a bottom of the cell container; the first electrode and the second electrode are connected to an electrical impedance analyzer; and in a downward linear motion of the driving device, the ceramic needle is pressed down into the cell container to detect the mechanical characteristics and electrical characteristics of cells.

2. The driving device for detecting mechanical characteristics and electrical characteristics of cells according to claim 1, wherein the mechanical characteristics detected comprise an elastic modulus, Poisson's ratio, a shear modulus, and a degree of deformation; and the electrical characteristics detected comprise impedance, a hysteresis frequency, conductivity, a dielectric constant, and cell membrane specific capacitance.

3. The driving device for detecting mechanical characteristics and electrical characteristics of cells according to claim 1, wherein a displacement of the driving device is divided into two steps: firstly, the piezoelectric stack, the bridge-type flexible hinge mechanism, the parallel hinge mechanism, the first metal connecting plate, the second metal connecting plate, the force sensor and the ceramic needle are driven to displace downwards by the lead screw guide rail and a metal adapter plate connected to a top of the lead screw guide rail; and secondly, the piezoelectric stack is arranged in the bridge-type flexible hinge mechanism, the piezoelectric stack is driven to make the bridge-type flexible hinge mechanism to stretch and then to drive the parallel flexible hinge mechanism to stretch and linearly move downwards.

4. A driving device for detecting mechanical characteristics and electrical characteristics of cells, comprising a first metal base, a guide rail, a piezoelectric module, a ceramic needle, a fine-tuning element, a cell container, a linear displacement sensor, and a force sensor, wherein the piezoelectric module is mounted on one side of the first metal base, the guide rail is slidingly mounted in the piezoelectric module, and the fine-tuning element is mounted on one side of the piezoelectric module and capable of adjusting a pressing force of the piezoelectric module on the guide rail; the piezoelectric module is capable of driving the guide rail to ascend and descend when deforms; a lower end of the guide rail is connected to an upper end of the ceramic needle and capable of driving the ceramic needle to ascend and descend; a first electrode is provided at a lower end of the ceramic needle, the cell container is located below the ceramic needle, a second electrode and cells are provided in the cell container, the first electrode corresponds to the second electrode in position; the force sensor is located at a lower end of the cell container, and the linear displacement sensor is configured to detect displacement of the guide rail.

5. The driving device for detecting mechanical characteristics and electrical characteristics of cells according to claim 4, further comprising a second metal base, wherein both the first metal base and the force sensor are mounted on the second metal base.

6. The driving device for detecting mechanical characteristics and electrical characteristics of cells according to claim 4, wherein the piezoelectric module comprises a housing, a symmetric flexible hinge, an asymmetric flexible hinge, and a piezoelectric stack; the housing is mounted on the first metal base, the symmetric flexible hinge and the asymmetric flexible hinge are vertically arranged and both mounted in the housing; the piezoelectric stack is mounted in the asymmetric flexible hinge, and capable of stretching and retracting in a vertical direction; and the guide rail is located in the housing, and located on one side of each of the symmetric flexible hinge and the asymmetric flexible hinge.

7. The driving device for detecting mechanical characteristics and electrical characteristics of cells according to claim 6, wherein the housing is mounted on the first metal base by screws, the symmetric flexible hinge and the asymmetric flexible hinge are mounted in the housing by screws.

8. The driving device for detecting mechanical characteristics and electrical characteristics of cells according to claim 6, wherein the fine-tuning element is mounted on one side, away from the guide rail, of the housing, and passes through the housing to act upon the symmetric flexible hinge and the asymmetric flexible hinge.

9. The driving device for detecting mechanical characteristics and electrical characteristics of cells according to claim 6, wherein a limit groove is formed in each of two opposite inner walls of the asymmetric flexible hinge, and two limit grooves are symmetric; a limit bump is formed at a position close to an outer wall of the guide rail and corresponding to the limit grooves of the asymmetric flexible hinge, and both ends of the piezoelectric stack are respectively embedded in the two limit grooves respectively, such that the piezoelectric stack is capable of driving the asymmetric flexible hinge to deform when stretching and retracting, and the limit bump is capable of driving the guide rail to displace.
